(19) United States
(12) Patent Application Publication
(10) Pub. No.: US 2009/0273074 A1
(43) Pub. Date: Nov. 5, 2009

(54) Bond wire loop for high speed noise isolation

(76) Inventor: Xiaoming Li, Irvine, CA (US)

Correspondence Address: WEIDE & MILLER - MINDSPEED, 7251 WEST LAKE MEAD BLVD., SUITE 530, LAS VEGAS, NV, 89128, US

(21) Appl. No.: 12/387,133

(22) Filed: Apr. 27, 2009

Related U.S. Application Data
(60) Provisional application No. 61/125,972, filed on Apr. 30, 2008.

(51) Int. Cl. H01L 23/49; H01L 23/488; H01L 21/60

(52) U.S. Cl. 257/692; 257/784; 438/121; 257/E23.023; 257/E23.024; 257/E21.509

(57) ABSTRACT

Semiconductor dies embodying electronic circuits are enclosed and protected within a package. To electrically access the die, the package includes external electrical leads which in turn connect to internal bond wires. The bond wires electrically connect the package to the die. As die density and circuit complexity increase, bond wire are placed in greater proximity. As a result, signal coupling between adjacent bond wires also increases and this coupling reduces circuit performance and input/output rates. A dissipation bond wire is provided adjacent the signal or supply bond wire acting as an aggressor. The dissipation bond wire has a first end connecting to the package and the second end connecting to the die or the package to form a conductive loop which dissipates unwanted coupling from an aggressor bond wire before the coupling couples into victim bond wire. The dissipation bond wire may be grounded.

### PRIORITY CLAIM

This application claims the benefit of and priority to U.S. Provisional Patent Application 61/125,972 filed Apr. 30, 2008 entitled Bond Wire Loop for High Speed Noise Isolation.

### FIELD OF THE INVENTION

The invention relates to die packaging technology and in particular to a method and apparatus for noise isolation in bond wires.

### RELATED ART

There exists a continuing demand for electronic devices that have greater functionality and speed. As such there has been, and continues to be, great strides in the development of new integrated circuit technologies that allow circuit designers to meet these needs. For example, electronic circuits increasingly operate at higher speeds and enjoy reductions in size as compared to circuits of a few years ago.

By way of background, an integrated circuit is often referred to as an electronic “chip” and it often comprises numerous subparts. In particular, a die or integrated circuit, which contains or comprises one or more circuits, is housed within a package that protects and secures the die. The die often comprises one or more metallic layers, one or more insulating layers, and one or more ion implanted regions. Most often, the outer top edge of the die contains numerous bonding pads to which extremely small wires (hereinafter wire bonds or bond wires) attach using a process referred to as wirebonding. These bond wires provide electrical input and output points between the package and the die.

The bond wires electrically attach to the package and, in turn, the package electrically connects to a circuit board or other structure configured to interface with the circuit. As is commonly understood, the package comprises a protective housing or container configured with numerous leads or contact points on its outer surface that provides electrical access, via conductive layers of the package to the bond wires and the die. The inner area of the package is created by injection molding using hot and fluid package material to thereby encapsulate the die and the bond wires.

Via the contact points or leads, access may be gained to the circuits on the die while the die is enclosed and protected by the package housing. For example, certain packages may have numerous leads extending from the outer edge of the package while other package configurations utilize a ball grid array configuration (BGA) to provide numerous contacts or solder points on the bottom surface of the package.

As a result of the advancements in integrated circuit technology, the devices continues to grow more complex while the number of electronic devices on the integrated circuit and the number of conductors, i.e. bus width, that connect to the die increases. Consequently, it may be necessary to utilize a greater and greater number of bond wires to electrically connect the die to the package. Thus, the density of the bond wires increases. Stated another way, the density of the die and package increases thereby reducing the distance between bond wires. In addition, as technology advances, the signals on the bond wires operate with less margin and at higher data rates.

A better understanding of the various components may be gained by reference to FIG. 1. As shown, FIG. 1 illustrates a prior art package configuration. A die 104 is located on a package 108 and one or more rows of bonding pads 112 are located on the outer edge of the die 104.

The package 108 has one or more rows of conductive traces 120A, 120B, 120C, 120D at least partially surrounding the die 104. The conductive traces 120A-120D comprise electrically accessible conductors, such as deposition layers, on the surface of the inner top layer of the package 108. In this embodiment, traces 120A and 120B comprise a common electrical node, such as for a supply voltage node and a ground node, respectively.

Certain of the conductive traces, namely trace 120C and trace 120D, have trace extensions extending to a via 134. For example, a trace extends from bonding pad 150 to via 134. The via 134 connects to a lower layer of the package which is routed accordingly to either of a ball grid array or a package lead, or directly to a solder ball.

Appropriate bond wires 130 are shown connecting between the bonding pads 104 on the die and a location on the trace 120A, 120B, 120C, 120D. As can be appreciated and seen in FIG. 1, in the area 136 near the die, the density of the bond wires 130 is high resulting in unwanted noise coupling between bond wires. Thus, as a drawback to the prior art, an aggressor signal may couple into adjacent or even non-adjacent victim wire bond. This coupling can be so significant that it limits data rates and can inhibit further die and package size reduction or density increases.

Prior art solutions also include increasing the distance between bond wires and expensive flip-chip solutions to minimize bond wire length. Both of these proposed solutions are undesirable and costly.

The method and apparatus disclosed herein overcomes the drawbacks associated with the prior art and provides additional advantages and benefits.

### SUMMARY

To overcome the drawbacks in the prior art and to provide additional benefits, disclosed herein is a die to package configuration comprising a die having one or more die bond pads and a package having one or more package bond pads. A signal bond wire is provided and connects to a die bonding pad and a package bond pad. A dissipation bond wire is provided adjacent the signal bond wire. The dissipation bond wire has a first end and a second end. The first end connects to the package and the second end connects to the die or the package to form a conductive loop such that the dissipation bond wire shields one or more other bond wires to reduce coupling from the signal bond wire to the one or more other bond wires. The conductive loop may be formed by having the two bond pads to which the dissipation bond wire connect also be electrically connected.

In one configuration the first end of the dissipation bond wire attaches to a package ground bonding pad and the second end of the dissipation bond wire attaches to substrate ground paddle. In one embodiment the second end of the dissipation bond wire connects to the package instead of the die. Furthermore, it is contemplated that the dissipation bond wire may have an arch height generally matching an arch height of the signal bond wire. The signal or supply bond wire may be defined as the aggressor and the bond wire into which the signal on the aggressor couples into is the victim. The dissipation bond wire may be closer to the signal or supply bond wire than any of the one or more other bond wires. To increase shielding or dissipation, the dissipation bond wire may comprise a rectangular wire or foil configuration with the long side of the rectangular wire configuration facing the signal or supply bond wire. The term signal or supply bond wire may be used interchangeably although the signal bond wire may generally be considered to be a bond wire carrying a signal and a supply bond wire is a bond wire or node having a supply voltage.

In another embodiment, a dissipation bond wire is provided having a first end and a second end wherein the first end connects to a package and a second end connects to the package or a die. In this configuration the dissipation bond wire is configured as a ground connected low impedance inductive loop to absorb and dissipate noise energy from one or more nearby signal bond wires. It is contemplated that the signal bond wire supplies a supply voltage. By way of example, if supplying a supply voltage the operations within the circuit, such switching or other dynamic use of the supply voltage may create transients, which in turn cause unwanted noise coupling to victim bond wires. The dissipation bond wire can absorb part of this noise before it reaches the victim.

In addition, the dissipation bond wire may have a path profile that matches the nearby signal bond wire generating noise energy. This configuration may further comprising a package and a die. In one embodiment the dissipation bond wire comprises foil. The dissipation bond wire may connect to one or more traces and the dissipation bond wire is part of a short circuit loop. To increase dissipation, the dissipation bond wire may be closer to a signal bond wire generating noise energy than any other bond wire.

Also disclosed is a method for reducing coupling between package to die bonding wires comprising providing a package and a die. Then, electrically connecting the package to the die with two or more bonding wires, wherein a first bonding wire of the two or more bonding carries a signal and at least some of the signal couples into a second bond wire of the two or more bonding wires. The method also connects a first end of a dissipation wire to the package and connects a second end of the dissipation wire to the package or the die. As part of the connecting, the dissipation wire is between the first bonding wire and the second bonding wire to thereby shield the second bonding wire from signal coupling from the first bonding wire.

In one configuration, the dissipation wire is connected to a substrate ground paddle. As part of the connecting, the dissipation wire may be made to have an arch height which is generally similar to an arch height of the first bonding wire. In one embodiment, the second end of the dissipation wire connects to a trace. In some embodiments the term trace may be considered a channel. It is contemplated that the signal may comprise a supply voltage.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 illustrates a top plan view of an exemplary prior art die to package electrical interconnect.

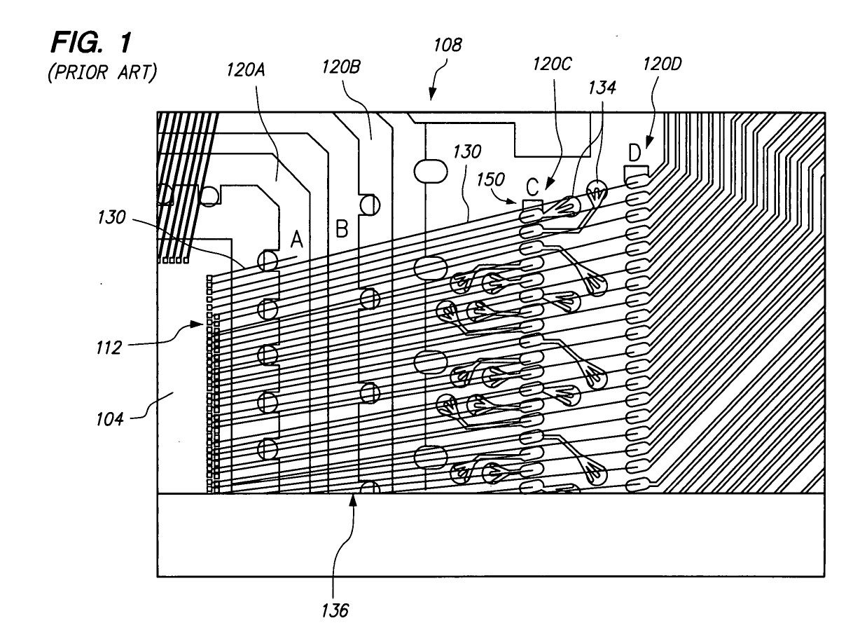

FIG. 2 illustrates a top plan view of a die and package.

FIG. 3 illustrates a perspective view of a package and die combination with connecting bond wires.

### DETAILED DESCRIPTION

A grounded bond wire loop for high speed noise isolation in modern high speed IC package is disclosed. The noise coupling through package bond wire is increasingly becoming a challenge for high speed chip design. Disclosed in this specification is a solution to this difficult problem with minimum cost impact.

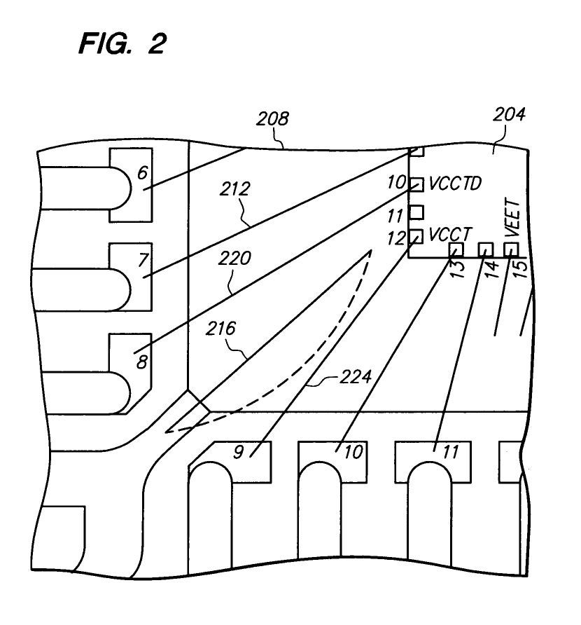

FIG. 2 illustrates a package 204 and die 208. Bonding wires 212 connect the die to the package. Disclosed herein is a bond wire loop 216 with both ends optionally grounded to form a very low impedance inductive loop. The loop may connect package to package as shown in FIG. 2 by the dissipation bond wire 216. The dissipation loop 216 is then inserted in between the bonding wires of two noisy and/or noise sensitive signals. The noise from any or both of the two signals will then couple to and short circuit in the grounded bond wire loop. The short circuit grounded loop (dissipation bond wire 216) will consume at least some of the noise energy before the noise energy reaches the adjacent signal bond wire. The grounded bond wire loop does not need to be bonded to any bond pad on chip, although it could be so configured. The term bond pad may refer to a bond bad, an I/O pad, or a bump pad. It optionally can be down bonded to the ground paddle on a package substrate as shown in FIG. 2. The bond wire may be grounded or ungrounded. In one embodiment the bonding location on the package 208 may comprise a conductive plate, which may be grounded.

By creating a loop which may behaeve as a coil, allowing the coil absorb noise energy, which in turn prevent the noise from coupling into victim bond wires. Energy transferred into the dissipation bond wire loop is dissipated within the loop (coil).

In one embodiment, the bond wire is the grounded bond wire. It combines with the package substrate ground paddle and package ground bonding pad at both end of the pin line to form a short circuit loop. In one configuration the paddle comprises a conducting layer for ground connection on a package. The loop may be placed in between two noise sensitive or generating bond wires. For example, in FIG. 2 the dissipation bond wire 216 may be placed between bond wires 220 and 224. In this example embodiment, the dissipation bond wire 216 is between bond wire 220 connecting chip pad 10 (VCCTD) and package landing pad 8, and the bond wire 224 connecting chip pad 12 (VCCT) and package bond pad 9. In this case the bond wire 220, 224 can be either a noise aggressor or victim, or both. The dissipation bond wire 216 absorbs unwanted noise or EMF that may couple from one of the bond wires 220, 224 to the other.

The grounded loop wire is most effective when the arch height of it matches the height of the higher one of the bond wires A and B. It is contemplated though that the dissipation bond wire may be any height or configuration. A 3-D field solver simulation has showed the effectiveness the grounded wire loop in noise reduction between bond wire A and B. Likewise, testing has confirmed the feasibility in construction of such a wire loop. This solution overcomes the unwanted noise coupling between the two supply bond wire which is preventing a die and package from going into production. In some embodiments, there may be provided more than one dissipation bond wire between aggressor and victim bond wires to absorb more noise or energy. Such bond wires could be in any configuration including stacked on top of each other. It is also contemplated that the dissipation bond wire 216 could also connect to the die 204.

In FIG. 2 the aggressor bond wire 220 connects to a voltage supply VCCTD. This voltage supply may contain noise, surges, or other transients that creates noise, including possibly high frequency noise that couples into bonding wire 224. The aggressor may also comprise a signal carrying bond wire such as a I/O bond wire.

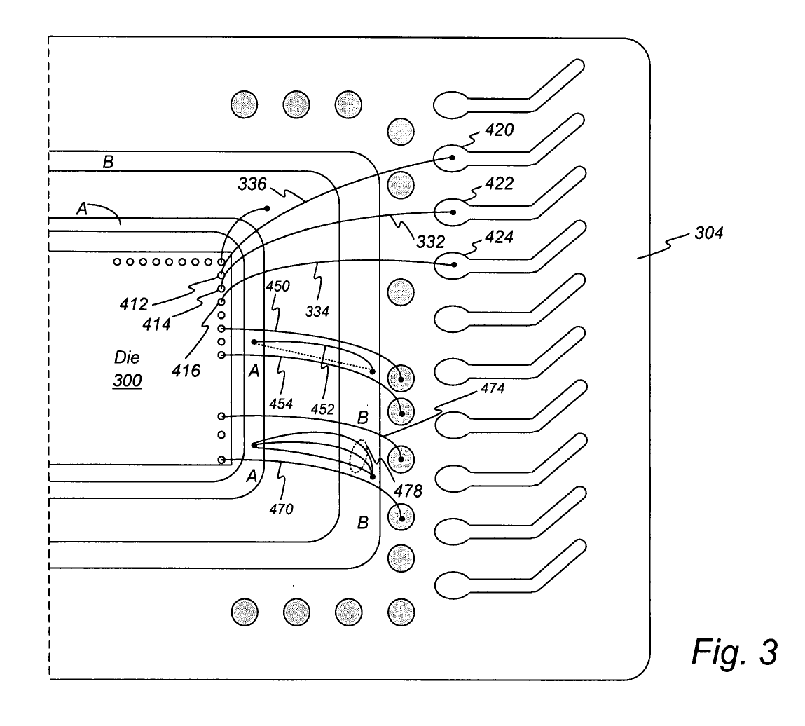

FIG. 3 illustrates another embodiment of the innovation. In FIG. 3, the die 300 has numerous bonding pads 412, 414, 416. The bond wires 336, 332, 334 connect to the package and the die as shown. At positions 420, 422, 424 the bond wires 336, 332, 334 connect to package bond pads on the package 304.

To reduce coupling of signals between conductor 336 and conductor 334, a dissipation bond wire 332 connects to the pads 414 and 422. In this embodiment the pads 414 and 422 are electrically connected to form a loop in connection with the bond wire 332. This loop absorbs and dissipates coupling energy between bond wires 336 and 334 to thereby reduce coupling between bond wires 336, 334. In one embodiment, the loop is a closed loop. For purposes of understanding, the bond wire 332 is referred to as a dissipation bond wire. In one embodiment the arc or path of the dissipation bond wire mirror or duplicates the arc or path of the adjacent bond wires 336, 334. By mirroring or duplicating the arc or path, the dissipating bond wire will absorb more energy from the aggressor bond wire (either or both of the adjacent bond wires) which will increase coupling into the dissipation bond wire and decrease cross coupling to the bond wires on the other sides of the dissipation bond wire.

In one embodiment the dissipation bond wire 332 is closer to one of the bond wires 336, 334 which will increase coupling from that bond wire. In one embodiment, the dissipation bond wire 332 is closer to the aggressor bond wire (the bond wire carrying the aggressor signal) than to the victim bond wire (the bond wire carrying the victim signal). In one embodiment the dissipation bond wire 332 comprises a foil or rectangular wire configuration with a long side of the wire configuration facing the aggressor bond wire. In one embodiment the size of the dissipation bond wire is larger in surface area or cross sectional surface area than the victim and/or aggressor bond wire. In one embodiment, the bond pad 414, 422 are grounded or connected to a common ground. In one embodiment the bond pad 414, 422 may be connected to a power node, which may further dissipate coupling energy. In one embodiment, greater than one dissipation bond wire may be placed and utilized between bond wires 336, 334. These bond wires may be arced in any manner to absorb coupling energy, which may be referred to as inductance coupling.

FIG. 3 also illustrates another exemplary configuration for establishing one or more dissipation bond wires. In this configuration, the bond wires 450 is the victim bond wire while bond wire 454 is the aggressor bond wire. The dissipation bond wire 452 is between the bond wires 450 and 454. In this configuration the dissipation bond wire 452 connects to trace A and trace B. Thus, instead of bonding the dissipation bond wire to a bond pad on the die, the dissipation bond wire 452 may connect to one or more traces. It is also contemplated that the bond wire may connect to a trace on one end and a die or package pad on the other end.

In one embodiment the trace A and trace B are connected to form a loop. The dashed line shows the electrical connection between the trace A and trace B. This loop may be considered a short circuit loop. In one embodiment, the trace A and trace B are connected to ground. In one embodiment, these traces are connected to a different node, such as a dissipation node. In one embodiment the dissipation bond wire and resulting loop perform shorting and shielding to reduce coupling. In one embodiment the traces A and B may comprise a power or voltage node or any two traces at the same potential and which form a loop. By shunting the noise from the dissipation bond wire 452 to or through a loop or larger conductor, the noise is absorbed and dissipated and not absorbed by a victim bonding wire.

FIG. 3 also illustrates a multiple dissipation wire configuration 478. In this example embodiment, the dissipation wires 478 are stacked one on top of another as shown between signal or supply bond wires 470, 474. In other embodiments, the multiple dissipation wires 478 may be arranged in different configurations as would be understood or tested to achieve maximum or desired noise blocking from the prespective of the victim bond wire. It is further contemplated that any number of dissipation bond wires may be placed between signal or supply bond wires. The dissipation bond wires may connect to the same bonding pad as shown, or to different locations. The multiple dissipation bond wires 478 may form a single loop or separate loops and may or may not be connected to ground.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims. While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A die to package configuration comprising
a die having one or more die bond pads;
a package having one or more package bond pads;
a signal bond wire connected to a bonding pad and a package bond pad;
a dissipation bond wire adjacent the signal bond wire having a first end and a second end and the first end connects to the package and the second end connects to the die or the package to form a conductive loop and wherein the dissipation bond wire shields one or more other bond wires to reduce coupling from the signal bond wire to the one or more other bond wires.

2. The configuration of claim 1, wherein the first end of the dissipation bond wire attaches to a package ground bonding pad and the second end of the dissipation bond wire attaches to substrate ground paddle.

3. The configuration of claim 1, wherein the second end connects to the package instead of the die.

4. The configuration of claim 1, wherein the dissipation bond wire has an arch height generally matching an arch height of the signal bond wire.

5. The configuration of claim 1, wherein the dissipation bond wire is closer to the signal bond wire than any of the one or more other bond wires.

6. The configuration of claim 1, wherein the dissipation bond wire comprises a rectangular wire configuration with the long side of the rectangular wire configuration facing the signal bond wire.

7. A dissipation bond wire comprising:
a dissipation bond wire having a first end and a second end wherein the first end connects to a package and a second end connects to the package or a die, wherein the dissipation bond wire is configured as a ground connected low impedance inductive loop to absorb and dissipate noise energy from one or more nearby signal bond wire.

8. The dissipation bond wire of claim 7, wherein the signal bond wire supplies a supply voltage.

9. The dissipation bond wire of claim 7, wherein the dissipation bond wire has a path profile that matches the nearby signal bond wire generating noise energy.

10. The dissipation bond wire of claim 7, further comprising a package and a die.

11. The dissipation bond wire of claim 7, wherein the dissipation bond wire comprise foil.

12. The dissipation bond wire of claim 7, wherein the dissipation bond wire connects to one or more traces.

13. The dissipation bond wire of claim 7, wherein the dissipation bond wire is part of a short circuit loop.

14. The dissipation bond wire of claim 7, wherein the dissipation bond wire is closer to a signal bond wire generating noise energy than any other bond wire.

15. A method for reducing coupling between package to die bonding wires comprising:
providing a package;
providing a die;
electrically connecting the package to the die with two or more bonding wires, wherein a first bonding wire of the two or more bonding carries a signal and at least some of the signal couples into a second bond wire of the two or more bonding wires;
connecting a first end of a dissipation wire to the package;
connecting a second end of the dissipation wire to the package or the die, wherein the dissipation wire is between the first bonding wire and the second bonding wire to thereby shield the second bonding wire from signal coupling from the first bonding wire.

16. The method of claim 15, wherein the dissipation wire is grounded.

17. The method of claim 15, wherein the dissipation wire is connected to a substrate ground paddle.

18. The method of claim 15, wherein the dissipation wire has an arch height which is generally similar to an arch height of the first bonding wire.

19. The method of claim 15, wherein the second end of the dissipation wire connects to a trace.

20. The method of claim 15, wherein the signal comprises a supply voltage.
